(19) United States
(12) Patent Application Publication
(10) Pub. No.: US 2026/0005153 A1
(43) Pub. Date: Jan. 1, 2026

(54) SEMICONDUCTOR PACKAGES WITH INTEGRATED ANTENNAS AND METHOD FOR FORMING THE SAME

(71) Applicant: JCET STATS ChipPAC Korea Limited, Incheon (KR)

(72) Inventors: MoonKyu CHUN, Gyeonggi-do (KR); HyeonJong KIM, Incheon (KR); YoungEun SEO, Incheon (KR)

(21) Appl. No.: 19/248,410

(22) Filed: Jun. 24, 2025

(30) Foreign Application Priority Data
Jun. 26, 2024 (CN) 202410837384.6

(51) Int. Cl. H01L 23/538; H01L 21/56; H01L 23/31; H01L 23/552; H01L 23/58

(52) U.S. Cl. CPC H01L 23/5386; H01L 21/56; H01L 23/3107; H01L 23/552; H01L 23/58

(57) ABSTRACT

A semiconductor package comprises: a package substrate; a semiconductor die mounted on the package substrate and electrically coupled to the package substrate; an encapsulant layer formed on the package substrate to at least encapsulate the semiconductor die; a shielding layer formed on the encapsulant layer to reduce or prevent electromagnetic interference to the semiconductor die from an external environment of the semiconductor package; and an antenna pattern formed on the encapsulant layer; and a set of interconnection structures extending through the encapsulant layer and electrically coupled between the antenna pattern and the package substrate.

### TECHNICAL FIELD

The present application generally relates to semiconductor technology, and more particularly, to semiconductor packages with integrated antennas and methods for forming such semiconductor packages.

### BACKGROUND OF THE INVENTION

Recently micrometer wave Antenna-in-Packages (AiP) with system and antenna integrated into one package have been adopted for mobile handsets and other portable multimedia devices. However, the compact AiP packages require reduced interface pitches, higher interface pin-counts, reduced thickness and high-level integration within the system-based packages.

Partial shielding technology has been utilized to achieve the conventional AiP packages. In particular, a region of a AiP package is encapsulated and shielded for semiconductor chips, and another region of the AiP package is not shielded and may be reserved for antennas that are embedded in the AiP package. However, integrating both the partial shielding layer and the antennas in a single AiP package makes the fabrication process complex and less flexible in the design or layout of antennas.

Therefore, a need exists for further improvement of existing AiP packages.

### SUMMARY OF THE INVENTION

An objective of the present application is to provide a semiconductor package with one or more antennas integrated therein.

According to an aspect of the present application, there is provided a semiconductor package, comprising: a package substrate; a semiconductor die mounted on the package substrate and electrically coupled to the package substrate; an encapsulant layer formed on the package substrate to at least encapsulate the semiconductor die; a shielding layer formed on the encapsulant layer to reduce or prevent electromagnetic interference to the semiconductor die from an external environment of the semiconductor package; and an antenna pattern formed on the encapsulant layer; and a set of interconnection structures extending through the encapsulant layer and electrically coupled between the antenna pattern and the package substrate.

According to another aspect of the present application, a method for forming a semiconductor package is provided, wherein the method comprises: providing a package substrate; mounting on the package substrate a semiconductor die and a set of interconnection structures; forming on the package substrate an encapsulant layer to encapsulate at least the semiconductor die and the set of interconnection structures, wherein the set of interconnection structures have top surfaces exposed from the encapsulant layer; forming a conductive layer on the encapsulant layer above both the semiconductor die and the set of interconnection structures, wherein the set of interconnection structures are electrically coupled to the conductive layer; and patterning the conductive layer to form an antenna pattern and a shielding layer on the encapsulant layer, wherein the antenna pattern is above the set of interconnection structures and electrically coupled to the set of interconnection structures, and the shielding layer is above the semiconductor die.

According to a further aspect of the present application, a method for forming a semiconductor package is provided, wherein the method comprises: providing a package substrate; mounting on the package substrate a semiconductor die, a first set of interconnection structures and a second set of interconnection structures, wherein the second set of interconnection structures have a height greater than that of the first set of interconnection structures; forming on the package substrate an encapsulant layer to encapsulate at least the semiconductor die and the first and second sets of interconnection structures, wherein the first set of interconnection structures have top surfaces exposed from the encapsulant layer, and the second set of interconnection structures have top ends protruding from the encapsulant layer; forming mask caps on the encapsulant layer to enclose the respective top ends of the second set of interconnection structures; forming a conductive layer on the encapsulant layer above the semiconductor die and the first and second sets of interconnection structures, wherein the first set of interconnection structures are electrically coupled to the conductive layer; removing the mask caps from the encapsulant layer to pattern the conductive layer to form an antenna pattern and a shielding layer, wherein the antenna pattern is above the first set of interconnection structures and electrically coupled to the first set of interconnection structures, and the shielding layer is above the semiconductor die; forming an additional encapsulant layer on the patterned conductive layer; forming an additional conductive layer on the additional encapsulant layer; and patterning the additional conductive layer to form an additional antenna pattern on the additional encapsulant layer, wherein the additional antenna pattern is above the second set of interconnection structures and electrically coupled to the second set of interconnection structures.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain the principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIG. 1 illustrates a semiconductor package 100 according to an embodiment of the present application.

FIG. 2 illustrates a semiconductor package 200 according to an embodiment of the present application.

FIG. 3 illustrates a semiconductor package 300 according to an embodiment of the present application.

FIG. 4 illustrates a semiconductor package 400 according to an embodiment of the present application.

FIGS. 5A to 5E illustrate a method for forming a semiconductor package according to an embodiment of the present application.

FIGS. 6A to 6I illustrate a method for forming a semiconductor package according to another embodiment of the present application.

FIGS. 7A to 7F illustrate a method for forming a semiconductor package according to a further embodiment of the present application.

FIGS. 8A to 8I illustrate a method for forming a semiconductor package according to yet a further embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

As mentioned above, for antenna-in-packages (AiP), integrating both a partial shielding layer and antennas in a single package may involve complicated fabrication processes. For example, some AiP packages may need to embed their integrated antennas in substrates of the AiP packages. Also, additional high dielectric molding materials may be needed to optimize antenna performance and reduce electrical length of antennas.

In order to resolve the above issues, a semiconductor package with one or more integrated antennas is proposed. In the semiconductor package, the antennas may be formed on an encapsulant layer along with an electromagnetic interference (EMI) shielding layer, and may be electrically coupled to a substrate of the semiconductor package via a set of interconnection structures that extend through the encapsulant layer. Optionally, the one or more antennas may be formed with the EMI shielding layer in a single deposition process such as a sputtering process, which simplifies the fabrication of such semiconductor package.

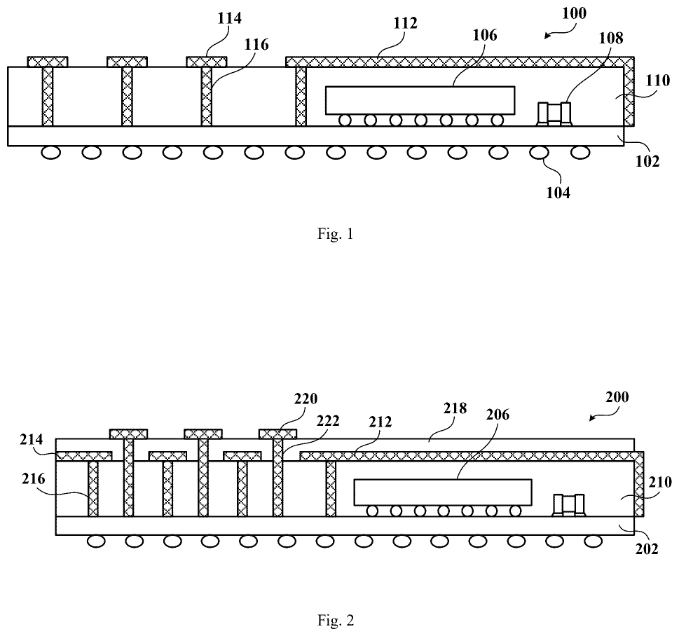

FIG. 1 illustrates a semiconductor package 100 according to an embodiment of the present application.

As shown in FIG. 1, the semiconductor package 100 includes a package substrate 102 where various components and other structures are mounted and formed. The package substrate 102 includes a first side facing upward in the direction shown in FIG. 1, and a second side opposite to the first side. In some embodiments, the package substrate 102 may be made of silicon or other semiconductor materials, or may include a printed circuit board (PCB), a carrier substrate, a ceramic substrate, a laminate interposer, a strip interposer, a leadframe, or other suitable substrates. In some examples, the package substrate 102 may include redistribution layers or structures having one or more dielectric layers and one or more conductive layers between and through dielectric layers. Thus, the various components and other structure on either one side or both sides of the package substrate 102 may be electrically coupled with each other to form an integrated electronic system.

In the embodiment shown in FIG. 1, most of the electronic components are mounted on the first side of the package substrate 102, only solder bumps 104 are mounted on the second side of the package substrate 102. As such, the electronic components mounted on the first side of the package substrate 102 can be electrically coupled to the solder bumps 104 through the package substrate 102, and be further electrically coupled to an external system such as a power system or a controller when the semiconductor package 100 is connected with such external system.

In particular, a semiconductor die 106 is mounted on the package substrate 102. The semiconductor die may include a wireless communication circuit and/or circuits with other functions. The semiconductor die 106 may be electrically coupled to the package substrate 102 via solder bumps or other similar conductive structures such as bonding wires. Furthermore, one or more other electronic components 108 may be mounted on the package substrate 102 close or adjacent to the semiconductor die 106. For example, the electronic components 108 may be another semiconductor die or dice, or may be discrete electronic devices such as resistors, capacitors, inductors, etc. An encapsulant layer 110 may be formed on the package substrate 102 to encapsulate the semiconductor die 106 and, optionally, the electronic components 108 which are mounted at the same side as the semiconductor die 106. In some embodiments, the encapsulant layer 110 may be made of a polymer composite material, such as epoxy resin with filler, epoxy acrylate with filler, or polymer with proper filler, but the scope of this application is not limited thereto. In the embodiment shown in FIG. 1, the encapsulant layer 110 is not formed on the second side of the package substrate 102 due to the existence of the solder bumps 104, but in some alternative embodiments, the encapsulant layer may also be formed on the second side of the package substrate 102, as will be elaborated below with reference to some other embodiments of the present application.

Still referring to FIG. 1, a portion of the package substrate 102 is occupied by the semiconductor die 106 and the electronic components 108, which may need shielding to avoid or reduce EMI interferences introduced into the semiconductor die 106. Accordingly, a shielding layer 112 is formed on the encapsulant layer 110 to reduce or prevent electromagnetic interferences to the semiconductor die 106 from an external environment of the semiconductor package 100. The shielding layer 112 is a partial shielding layer, as only a portion of the encapsulant layer 110 which encapsulates the semiconductor die 106 and the electronic components 108 is covered by the shielding layer 112. Optionally, the shielding layer 112 may extend from a top surface of the encapsulant layer 110 to one, two, or three lateral surfaces of the encapsulant layer 110 to form a relatively complete shielding for the semiconductor die 106.

Other than the portion of the encapsulant layer 110 that is covered by the shielding layer 112, the other portion of the encapsulant layer 110 is exposed from the shielding layer 112. In such region, one or more antenna patterns 114 may be formed for transmitting to and/or receiving wireless signals from the external environment. The antenna patterns 114 may be formed with any desired shapes such as square, zig-zag, spiral or other suitable shapes. Each antenna pattern 114 may have two or more nodes that can be electrically coupled to respective interconnection structures 116 which extend through the encapsulant layer 110 under the antenna pattern 114. As such, the antenna pattern 114 can be electrically coupled with the package substrate 102 through a set of interconnection structures 116. In some embodiments, the interconnection structures 116 may be conductive bars or pillars such as copper pillars which can be mounted on the package substrate 102 individually.

As can be seen from the embodiment shown in FIG. 1, depending on actual needs of antennas for wireless communication, one or more antenna patterns may be formed on the encapsulant layer 110. Furthermore, the antenna patterns may be formed separately, for example, using a patterning process, and thus they may have different antenna radiation characteristics compared to the limited antenna patterns and arrays of conventional AiP packages.

Similar as coupling the antenna patterns 114 with the package substrate 102, one or more interconnection structures 116 that extend through the encapsulant layer 110 may be formed to electrically couple the shielding layer 112 with the package substrate 102. As such, the shielding layer 112 may serve as a ground plane for the semiconductor package 100. It should be noted that for simplicity conductive layers and/or conductive pads in the package substrate 102 where the interconnection structures 116 are connected or coupled are not shown in FIG. 1.

FIG. 2 illustrates a semiconductor package 200 according to another embodiment of the present application. Different from the semiconductor package 100 shown in FIG. 1, the semiconductor package 200 may have two encapsulant layers and two layers of antenna patterns, each of which lies on one of the encapsulant layers.

In particular, the semiconductor package 200 includes a package substrate 202. A first encapsulant layer 210 is formed on the package substrate 202 to encapsulate various components thereon, including a semiconductor die 206. A shielding layer 212 and one or more antenna patterns 214 may be formed on the first encapsulant layer 210, which are generally at a same level relative to the package substrate 202. Furthermore, a second encapsulant layer 218 may be formed on the first encapsulant layer 210, the shielding layer 212 and the antenna patterns 214. In some embodiments, the second encapsulant layer 218 may be made of the same material as the first encapsulant layer 210, or may be made of a different material from the first encapsulant layer 210. The additional second encapsulant layer 218 elevates a top surface of the entire semiconductor package 200, and thus, one or more additional antenna patterns 220 may be formed on the second encapsulant layer 218. Similar as interconnection structures 216 that electrically couple the antenna patterns 214 on the lower first encapsulant layer 210 with the package substrate 202, a set of additional interconnection structures 222 may be formed on the package substrate 202, which extend through the first encapsulant layer 210 and the second encapsulant layer 218 and are electrically coupled between the additional antenna patterns 220 and the package substrate 202. In some embodiments, the antenna patterns 214 and the additional antenna patterns 220 may form an antenna array that may be used by the semiconductor package 200 for signal transmission and receiving purposes.

It can be appreciated that the embodiments shown in FIGS. 1 and 2 are only exemplary and not limiting. For example, although multiple antenna patterns are shown in the embodiments, one antenna pattern at one layer or two antenna patterns at respective two layers may be integrated within a semiconductor package in some other embodiments of the present application. Also, more electronic components may be integrated within the semiconductor packages. Furthermore, although the antenna patterns are formed at the same side as the semiconductor die and the shielding layer in the embodiments shown in FIGS. 1 and 2, the antenna patterns may be formed at a different side from the semiconductor die and the shielding layer in some other embodiments of the present application.

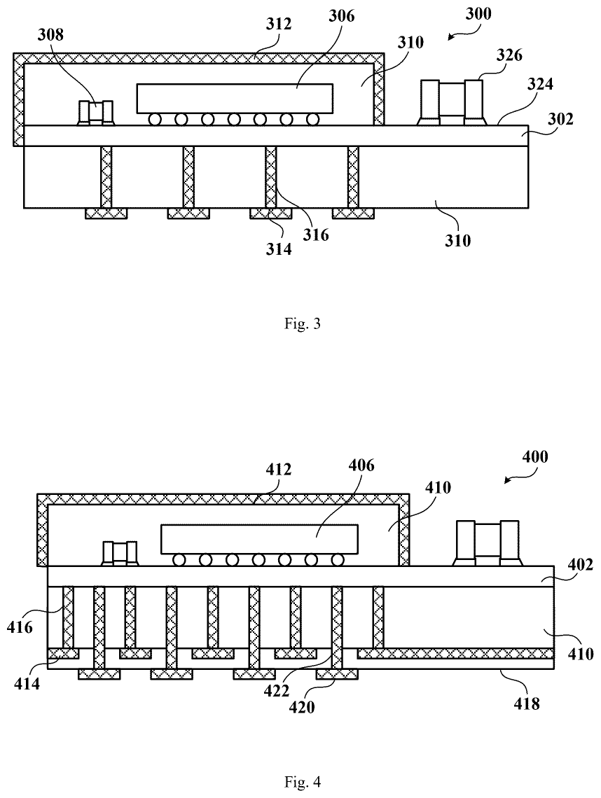

FIG. 3 illustrates a semiconductor package 300 according to an embodiment of the present application.

As shown in FIG. 3, the semiconductor package 300 includes a package substrate 302 where various components and other structures are mounted and formed. The package substrate 302 includes a first side facing upward in the direction shown in FIG. 3, and a second side opposite to the first side. In the embodiment, a semiconductor die 306 is mounted on the first side of the package substrate 302 via solder bumps or other similar conductive structures. Furthermore, one or more other electronic components 308 may be mounted on the first side of the package substrate 302 close or adjacent to the semiconductor die 306. An encapsulant layer 310 may be formed on the first side of the package substrate 302 to encapsulate the semiconductor die 306 and, optionally, the electronic components 308 which are mounted at the same side as the semiconductor die 306. A shielding layer 312 is formed on the encapsulant layer 310 on the first side of the package substrate 302 to reduce or prevent electromagnetic interferences to the semiconductor die 306 from an external environment of the semiconductor package 300. Optionally, the shielding layer 312 may extend from the encapsulant layer 310 to a side wall of the package substrate 302 which is close to the encapsulant layer 310, for example, such that the shielding layer 312 may serve as a ground plane for the semiconductor package 300 besides for EMI shielding.

Furthermore, the encapsulant layer 310 is also formed on the second side of the package substrate 302, on which one or more antenna patterns 314 may be formed for transmitting and/or receiving wireless signals from the external environment. In some embodiments, the encapsulant layer 310 on both sides of the package substrate 302 may be formed in a single molding process, or may be formed in two separate molding processes. Each antenna pattern 114 may have two or more nodes that can be electrically coupled to respective interconnection structures 316 which extend through the encapsulant layer 310 on the second side of the package substrate 302. As such, the antenna pattern 314 can be electrically coupled with the package substrate 302 through a set of interconnection structures 316, and further electrically coupled with the semiconductor die 306 and the various electronic components 308 on the first side of the package substrate 302.

In some embodiments, the package substrate 302 may include a connection region 324 at its first side, which is exposed from the encapsulant layer 310 and the shielding layer 312. In this connection region 324, a board to board connector 326 may be mounted on and electrically coupled with the package substrate 302, and further with the semiconductor die 306. As such, the semiconductor package 300 may be connected with an external system through the board to board connector 326.

FIG. 4 illustrates a semiconductor package 400 according to an embodiment of the present application. Different from the semiconductor package 300 shown in FIG. 3, the semiconductor package 400 may have two encapsulant layers and two layers of antenna patterns, each of which lies on one of the encapsulant layers.

In particular, the semiconductor package 400 includes a package substrate 402, which has a first side and a second side opposite to the first side. A first encapsulant layer 410 is formed on the package substrate 402 to encapsulate various components thereon, including a semiconductor die 406. A shielding layer 412 and one or more antenna patterns 414 may be formed on the first encapsulant layer 410, at the first side and the second side of the package substrate 402, respectively.

Furthermore, a second encapsulant layer 418 may be formed on the first encapsulant layer 410 at the second side of the package substrate 402. The additional second encapsulant layer 418 extends along a bottom surface of the entire semiconductor package 400, and thus, one or more additional antenna patterns 420 may be formed on the second encapsulant layer 418 at the second side of the package substrate 402. Similar as interconnection structures 416 that electrically couple the antenna patterns 414 on the first encapsulant layer 410 with the package substrate 402, a set of additional interconnection structures 422 may be formed on the package substrate 402, which extend through the first encapsulant layer 410 and the second encapsulant layer 418 at the second side of the package substrate 402, and are electrically coupled between the additional antenna patterns 420 and the package substrate 402.

Various processes can be used to form the semiconductor packages described in the above embodiments of the present application.

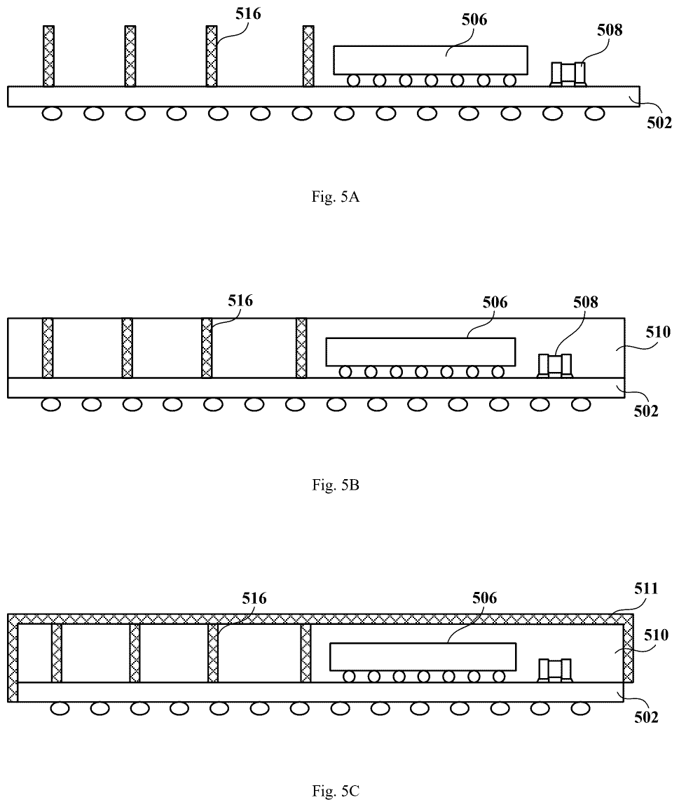

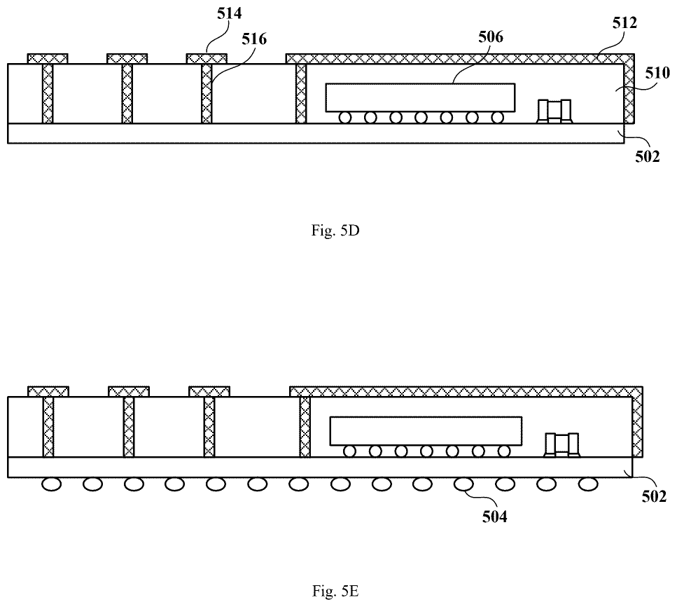

FIGS. 5A to 5E illustrate a method for forming a semiconductor package according to an embodiment of the present application. For example, the method can be used to form the semiconductor package 100 shown in FIG. 1.

As shown in FIG. 5A, a package substrate 502 is provided. Various components and structures may be mounted on the package substrate 502, or particularly on a front side of the package substrate 502. In the embodiment, the package substrate 502 is generally divided into two regions, i.e., a chip region and an antenna region. In the chip region, a semiconductor die 506 and at least one electronic component 508 are mounted, for example, via solder bumps or similar interconnection structures. Furthermore, in the antenna region where one or more antenna or antenna patterns will be formed subsequently, a set of interconnection structures 516 are mounted and fixed onto the package substrate 502, for example, through solder paste or similar conductive adhesives. These interconnection structures 516 may be conductive posts or pillars which may have sufficient strength to withstand shocks or other mechanical operations during subsequent processes. Optionally, one or more interconnection structures may be also formed in or close to the chip region, which may be used to electrically couple a shielding layer to be formed to the package substrate 502. It can be appreciated that the interconnection structures 516 may be connected to conductive pads exposed from the package substrate 502 such that they can be electrically coupled to the package substrate 502, especially conductive structures within the package substrate 502, and further to some other devices that may be electrically connected to the package substrate 502.

Next, as shown in FIG. 5B, an encapsulant layer 510 may be formed on the package substrate 502 to encapsulate at least the semiconductor die 506 and the set of interconnection structures 516. Optionally, the electronic components 508 may also be fully covered and encapsulated by the encapsulant layer 510. In some embodiments, the encapsulant layer 510 may be made of a polymer composite material, such as epoxy resin with filler, epoxy acrylate with filler, or polymer with proper filler, which may be formed using a molding process such as a film assisted molding process. Particularly, during the film assisted molding process, a flexible film may be attached to an inside of a top chase to avoid damages or movement of the interconnection structures 516. The interconnection structures 516 may have a height greater than that of the semiconductor die 506 and the electronic components 508, and thus after the encapsulant layer 510 is formed, respective top surfaces the interconnection structures 516 may be exposed from the encapsulant layer 510. In some embodiments, the interconnection structures 516 may not be exposed from the encapsulant layer 510 due to excessive molding materials formed on the package substrate 502. In that case, a grinding process may be performed to remove the excess molding materials above the interconnection structures 516.

Next, as shown in FIG. 5C, a conductive layer 511 may be formed on the encapsulant layer 510 above both the semiconductor die 506 and the interconnection structures 516. The conductive layer 511 may be formed to cover the entirety of the encapsulant layer 510 at the front side of the package substrate 502, i.e., to cover the top surface and lateral surfaces of the encapsulant layer 510. In some embodiments, the conductive layer 511 may be formed using a deposition process such as a sputtering process, in both the antenna region and the chip region of the package substrate 502. Since the interconnection structures 516 are exposed from the encapsulant layer 510, they can be connected with and thus electrically coupled to the conductive layer 511.

Next, as shown in FIG. 5D, the conductive layer may be patterned to form one or more antenna patterns 514 and a shielding layer 512 on the encapsulant layer 510. The antenna patterns 514 are above the set of interconnection structures 516, i.e., in the antenna region, while the shielding layer 512 is above the semiconductor die 506, i.e., in the chip region. Due to the exposed top surfaces of the interconnection structures 516, the antenna patterns 514 and the shielding layer 512 may be both electrically coupled to the interconnection structures 516 and thus to the package substrate 502. In some embodiments, a laser ablation process or other similar etching process may be used to pattern the conductive layer. It can be appreciated that the antenna patterns 514 so formed may have various shapes as desired.

Next, as shown in FIG. 5E, solder bumps 504 may be formed on a back side of the package substrate 502, which can be electrically coupled to the package substrate 502 as well as the components and structures on the front side of the package substrate 502. In this way, the semiconductor package with one or more antenna patterns integrated therein is formed.

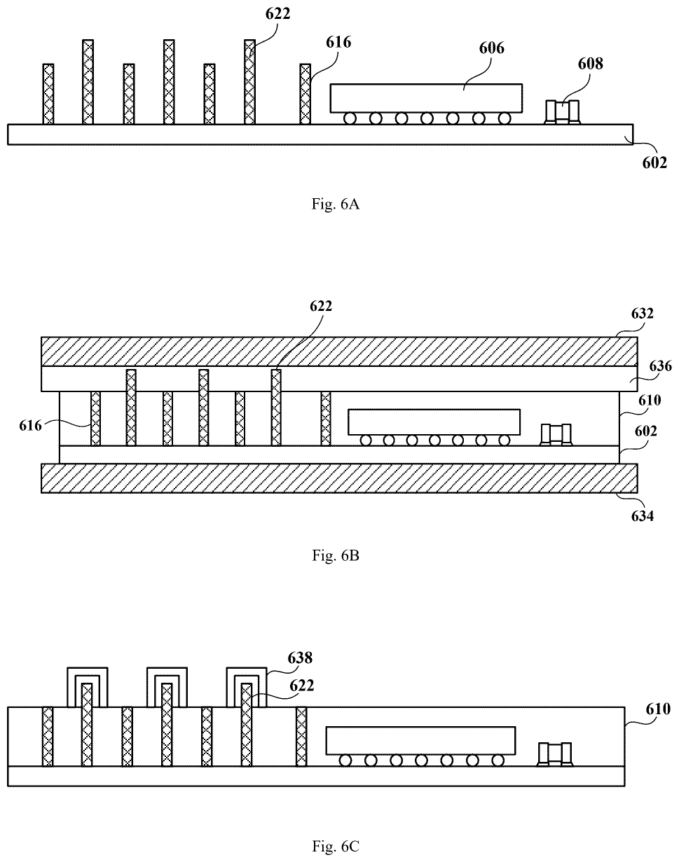

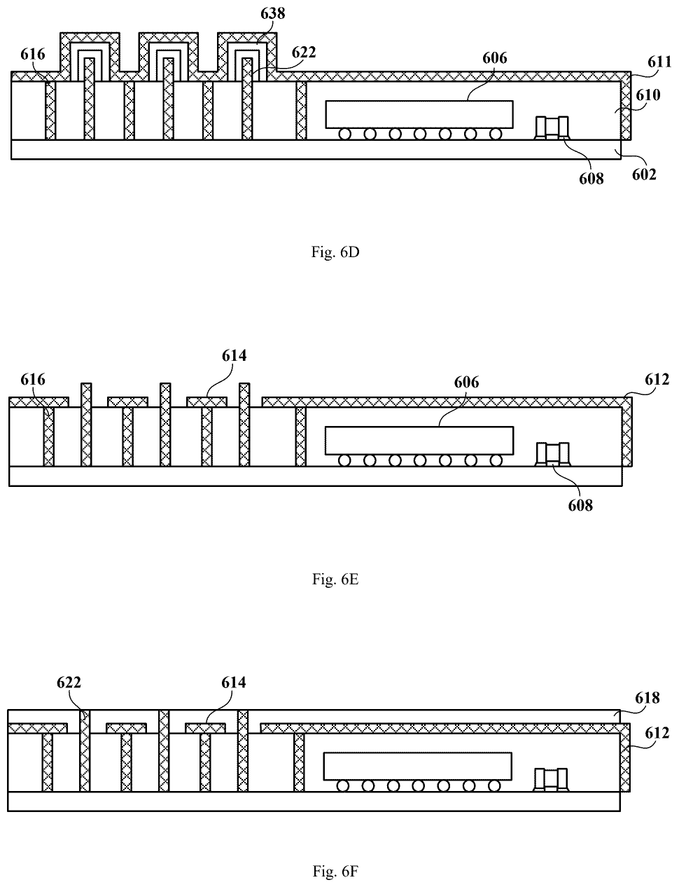

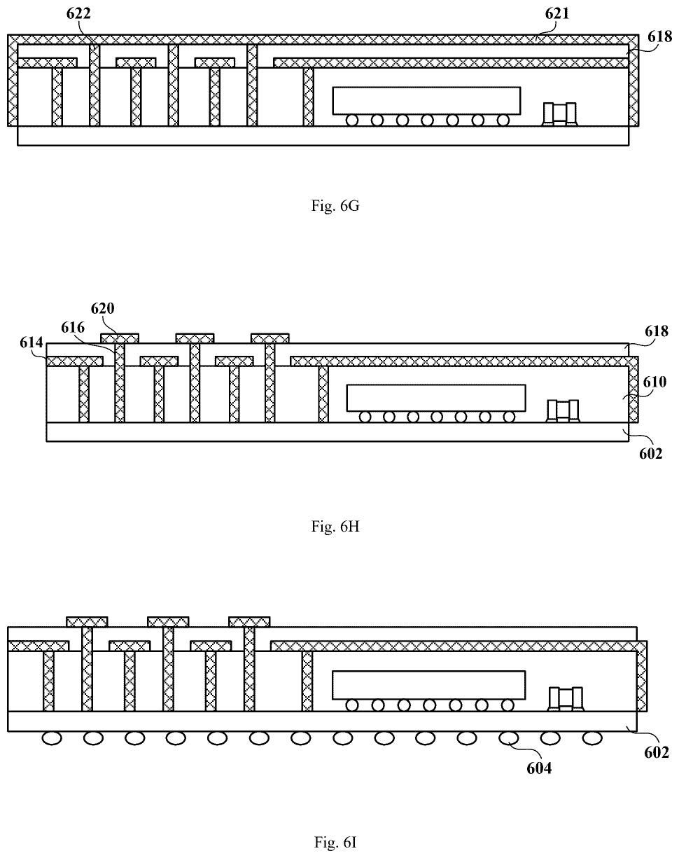

FIGS. 6A to 6I illustrate a method for forming a semiconductor package according to another embodiment of the present application. For example, the method can be used to form the semiconductor package 200 shown in FIG. 2, which have two or more layers of antenna patterns at different heights relative to a substrate of the semiconductor package. In that case, two layers of encapsulant layers may be formed to place the two layers of antenna patterns.

As shown in FIG. 6A, a package substrate 602 is provided. A semiconductor die 606 and at least one electronic component 608 are mounted, for example, via solder bumps or similar interconnection structures in a chip region. Furthermore, in an antenna region different from the chip region where one or more antenna or antenna patterns will be formed subsequently, a first set of interconnection structures 616 and a second set of interconnection structures 622 are mounted and fixed onto the package substrate 602, for example, through solder paste or similar conductive adhesives. These interconnection structures 616 and 622 may be conductive posts or pillars which have sufficient strength to withstand shocks or other mechanical operations during subsequent processes. Optionally, one or more interconnection structures may be also formed in or close to the chip region, which may be used to electrically couple a shielding layer to be formed to the package substrate 602.

In particular, both the first set of interconnection structures 616 and the second set of interconnection structure 622 have heights greater than the semiconductor die 606 and the electronic components 608, but the second set of interconnection structure 622 are higher than the first set of interconnection structures 616.

Next, as shown in FIG. 6B, a film assisted molding process may be performed to the package substrate 602 to form a first encapsulant layer 610 on the package substrate 602, which encapsulates at least the semiconductor die 606 and the first set of interconnection structures 616. The film assisted molding process may use a top chase 632 and a bottom chase 634 to form a chamber in which the package substrate 602 is accommodated. During the molding process, a flexible film 636 that is attached onto a bottom of the top chase 632 may be in contact with the second set of interconnection structures 622 and deform to accommodate respective top ends of the interconnection structures 622 which are higher than top surfaces of the first interconnection structures 616. In this way, the second set of interconnection structures 622 may not be moved or damaged during the molding process. At the same time, the flexible film 636 may also be in contact with top surfaces of the first interconnection structures 622. Then, a molding material may be filled into the chamber between the top chase 632 and the bottom chase 634 to form the first encapsulant layer 610.

After the film-assisted molding process, the first encapsulant layer 610 is formed. In particular, the first set of interconnection structures 616 have their top surfaces exposed from the first encapsulant layer 610, and the second set of interconnection structures 622 have top ends protruding from the first encapsulant layer 610. A height of the top ends of the second set of interconnection structures 622 may depend on a distance between the two layers of antenna patterns to be formed.

Next, as shown in FIG. 6C, mask caps 638 may be formed on the first encapsulant layer 610 to enclose the respective top ends of the second set of interconnection structures 622 which are above the first encapsulant layer 610. In some embodiments, the mask caps 638 may be formed of certain materials such as polymers, wax or other suitable materials that can be easily removed from the first encapsulant layer 610.

Next, as shown in FIG. 6D, a conductive layer 611 is formed on the first encapsulant layer 610. In the embodiment, the conductive layer 611 is at a front side of the package substrate 602, where the various components are formed. Therefore, the conductive layer 611 can be formed above the semiconductor die 606, optionally above the electronic components 608, and above the first and second sets of interconnection structures 616 and 622. The conductive layer 611 may cover an entirety of the first encapsulant layer 610, including the top surface and a least some lateral surfaces of the first encapsulant layer 610. In some embodiments, the conductive layer 611 may be formed using a deposition process such as a sputtering process. Since the first set of interconnection structures 616 are exposed from the first encapsulant layer 610, they can be connected with and thus electrically coupled to the conductive layer 611.

Next, as shown in FIG. 6E, the mask caps may be removed from the first encapsulant layer 610 to pattern the conductive layer to form one or more antenna patterns 614 and a shielding layer 612. In particular, the antenna patterns 614 are above the first set of interconnection structures 616 and electrically coupled to the first set of interconnection structures 616, and the shielding layer 612 is above the semiconductor die 606 and optionally above the electronic components 608. It can be appreciated that the antenna patterns 614 may have respective layouts complementary to the layouts of the mask caps removed from the first encapsulant layer 610. Therefore, the mask caps may be preformed to have respective layouts according to the antenna patterns 614 so formed. In some optional embodiments, a laser ablation process or other similar etching process may be used to further pattern the conductive layer. Also, since there is no mask cap formed above the semiconductor die 606 and the electronic components 608, the shielding layer 612 may have a continuous coverage over the portion of the encapsulant layer 606.

Since the mask caps are removed, the top ends of the second set of interconnection structures 622 which are previously enclosed by the mask caps are exposed from the first encapsulant layer 610. Next, as shown in FIG. 6F, a second encapsulant layer 618 is formed on the patterned conductive layer, i.e., on the antenna patterns 614 and the shielding layer 612. In particular, the second set of interconnection structures 622 may be substantially encapsulated by the second encapsulant layer 618, with their respective top surfaces exposed from the second encapsulant layer 618.

Next, as shown in FIG. 6G, a second conductive layer 621 may be formed on the second encapsulant layer 618. The second conductive layer 621 may be connected with the exposed top surfaces of the second set of interconnection structures 622 and thus electrically coupled thereto. In some embodiments, the second conductive layer 621 may be formed using a deposition process such as a sputtering process.

Next, as shown in FIG. 6H, the second conductive layer may be patterned, for example, using a laser ablation process, to form one or more antenna patterns 622 on the second encapsulant layer 618. The antenna patterns 622 and the antenna patterns 614 are respectively formed on the two encapsulant layers 618 and 610 at different heights from the package substrate 602. It can be appreciated in some other embodiments, more layers of antenna patterns may be formed on the package substrate 602 similarly, which will not be elaborated herein.

Next, as shown in FIG. 6I, solder bumps 604 may be formed on a back side of the package substrate 602, which can be electrically coupled to the package substrate 602 as well as the components and structures on the front side of the package substrate 602. In this way, the semiconductor package with one or more antenna patterns integrated therein is formed.

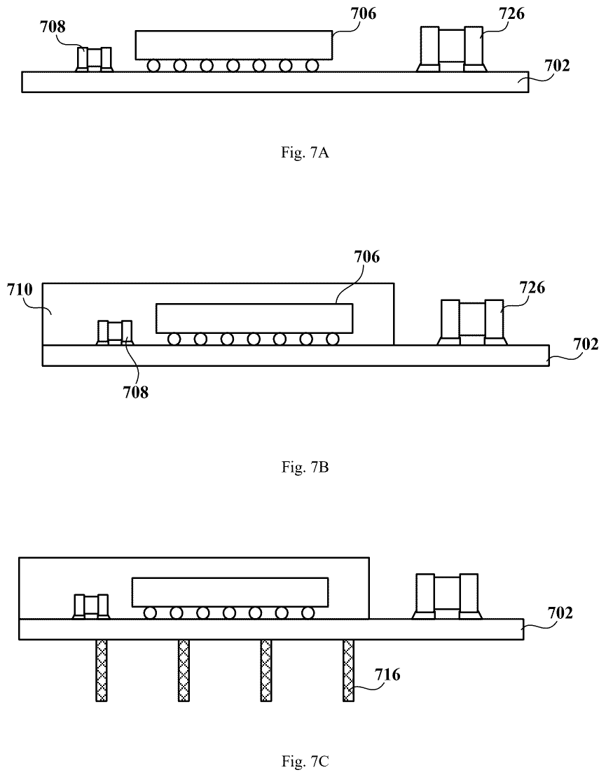

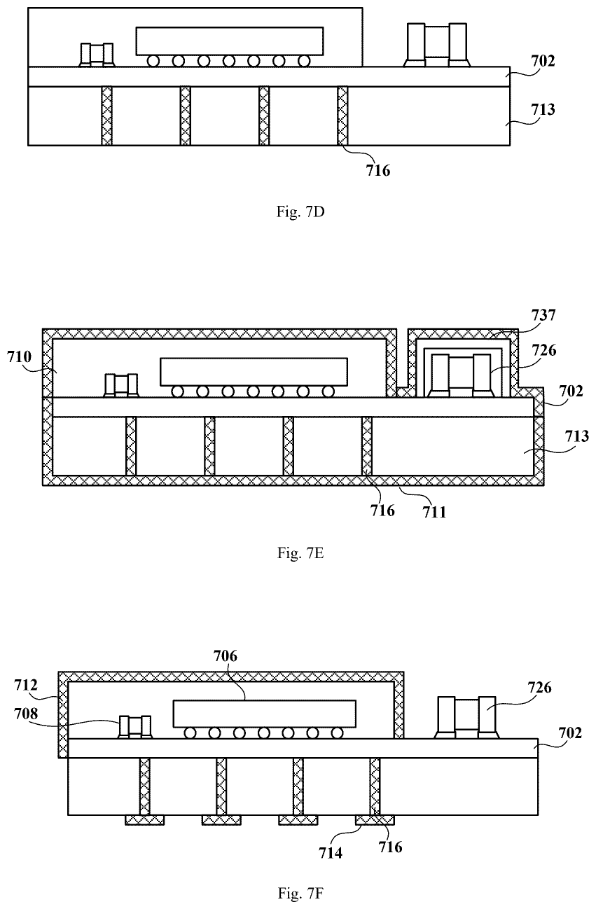

FIGS. 7A to 7F illustrate a method for forming a semiconductor package according to a further embodiment of the present application. For example, the method can be used to form the semiconductor package 300 shown in FIG. 3.

As shown in FIG. 7A, a package substrate 702 is provided. Various components and structures may be mounted on the package substrate 702, or particularly on a front side of the package substrate 702. In the embodiment, the package substrate 702 is generally divided into two regions, i.e., a chip region and a connector region. In the chip region, a semiconductor die 706 and at least one electronic component 708 are mounted, for example, via solder bumps or similar interconnection structures. Furthermore, in the connector region a board-to-board connector 726 is mounted, which is electrically coupled to the package substrate 702.

Next, as shown in FIG. 7B, a first encapsulant layer 710 may be formed on a portion of the front side of the package substrate 702, to encapsulate the semiconductor die 706 and the at least one electronic component 708 but expose the board-to-board connector 726, i.e., expose the connector region.

Next, as shown in FIG. 7C, a set of interconnection structures 716 may be mounted on a back side of the package substrate 702. In this way, both the front side and the back side of the package substate 702 may be utilized to mount components and structures of the semiconductor package to be formed, improving its compactness.

Next, as shown in FIG. 7D, a second encapsulant layer 713 may be formed on the back side of the package substrate 702 to encapsulate the set of interconnection structures 716, only having respective top surfaces of the interconnection structures 716 exposed.

Next, as shown in FIG. 7E, a mask cap 737 may be disposed on the front side of the package substrate 702 to enclose the board-to-board connector 726. Then a deposition process may be performed to the package substrate 702 at both the front side and the back side to form a conductive layer 711 on both the first encapsulant layer 710 at the front side and the second encapsulant layer 713 at the back side of the package substrate 702. It can be appreciated that in some embodiments the conductive layer 711 may be formed in two steps, i.e., a first step of forming the conductive layer 711 at the front side of the package substrate 702, and a second step of forming the conductive layer 711 at the back side of the package substrate 702 after the package substrate 702 is flipped. The conductive layer 711 can be connected with the set of interconnection structures 716 and thus electrically coupled thereto.

Next, as shown in FIG. 7F, the conductive layer may be patterned to form one or more antenna patterns 714 at the back side of the package substrate 702, and a shielding layer 712 at the front side of the package substrate 702. The antenna patterns 714 are below the set of interconnection structures 716, while the shielding layer 712 is above the semiconductor die 706 and the electronic components 708. Due to the exposed top surfaces of the interconnection structures 716, the antenna patterns 714 may be electrically coupled to the interconnection structures 716 and thus to the package substrate 702. In some embodiments, a laser ablation process or other similar etching process may be used to pattern the conductive layer. Also, the mask cap which previously enclosed the board-to-board connector 726 is removed from the package substrate 702 as well. The mask cap may not be in connection with the first encapsulant layer 710, allowing the shielding layer 712 the remains on the package substrate 702 to be connected with the package substrate 702. In this way, the semiconductor package with one or more antenna patterns integrated therein is formed.

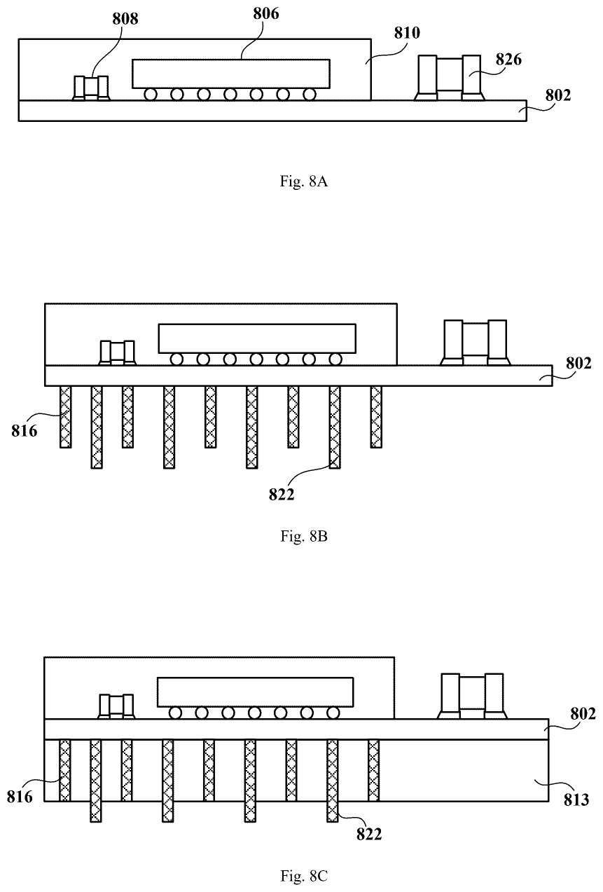

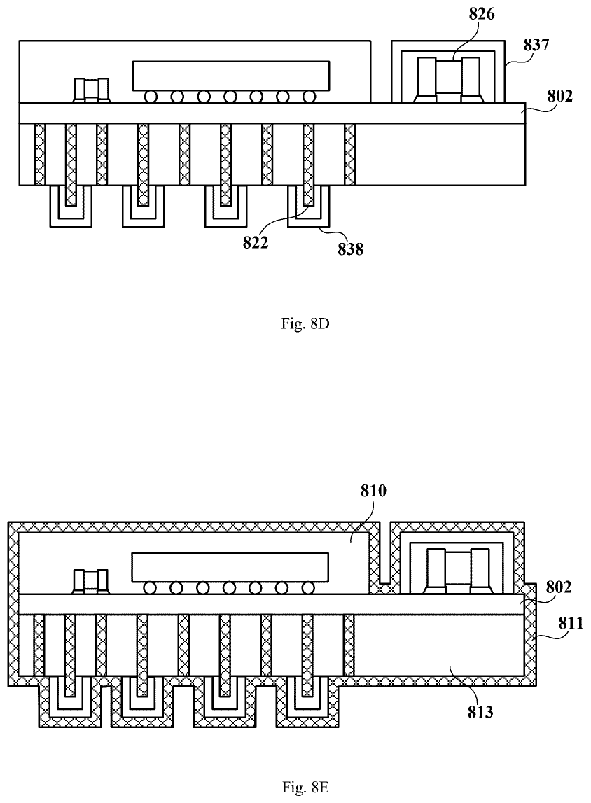

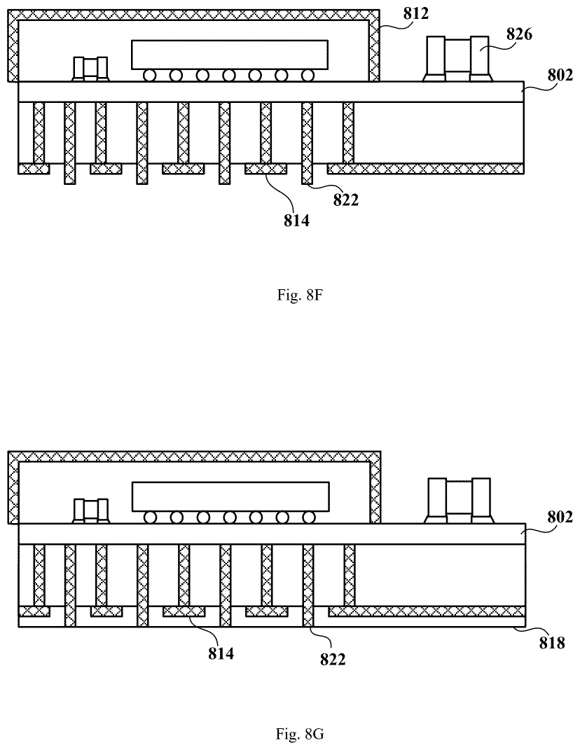

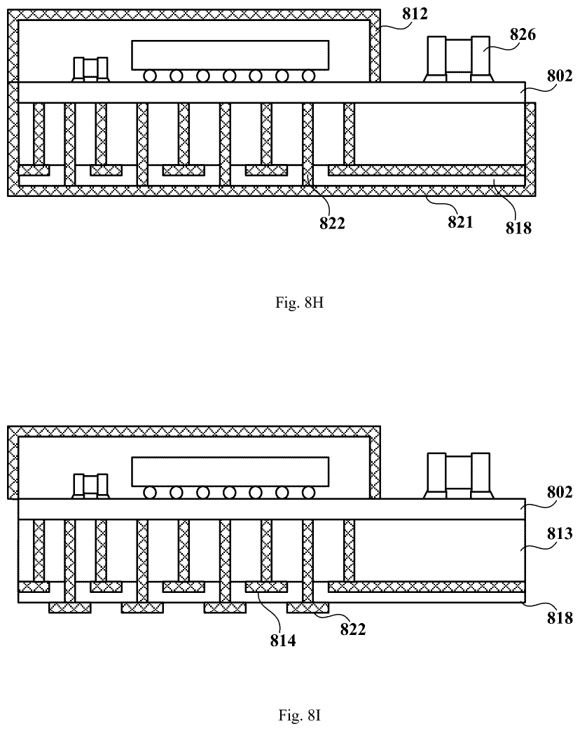

FIGS. 8A to 8I illustrate a method for forming a semiconductor package according to yet a further embodiment of the present application. For example, the method can be used to form the semiconductor package 400 shown in FIG. 4.

As shown in FIG. 8A, a package substrate 802 is provided. Various components and structures may be mounted on the package substrate 802, or particularly on a front side of the package substrate 802. In the embodiment, the package substrate 802 is generally divided into two regions, i.e., a chip region and a connector region. In the chip region, a semiconductor dic 806 and at least one electronic component 808 are mounted, for example, via solder bumps or similar interconnection structures. Furthermore, in the connector region a board-to-board connector 826 is mounted, which is electrically coupled to the package substrate 802. A first encapsulant layer 810 may be formed on a portion of the front side of the package substrate 802, to encapsulate the semiconductor die 806 and the at least one electronic component 808 but expose the board-to-board connector 826, i.e., expose the connector region.

Next, as shown in FIG. 8B, a first set of interconnection structures 816 and a second set of interconnection structures 822 are mounted and fixed onto a back side of the package substrate 802, for example, through solder paste or similar conductive adhesives. The second set of interconnection structure 822 are higher than the first set of interconnection structures 816 relative to the back surface of the package substrate 802.

Next, as shown in FIG. 8C, a film assisted molding process may be performed to the package substrate 802 to form a second encapsulant layer 813 on the package substrate 802, which encapsulates the first set of interconnection structures 816 and the second set of interconnection structure 822. Details of the film assisted molding process may be referred to the embodiment shown in FIGS. 6A to 6I which will not be elaborated in detail. After the film-assisted molding process, the second encapsulant layer 813 is formed. In particular, the first set of interconnection structures 816 have their top surfaces exposed from the second encapsulant layer 813, and the second set of interconnection structures 822 have top ends protruding from the second encapsulant layer 813. A height of the top ends of the second set of interconnection structures 822 may depend on a distance between the two layers of antenna patterns to be formed.

Next, as shown in FIG. 8D, mask caps 837 and 838 may be formed on the encapsulant layers at both sides of the package substrate 802, to enclose the board-to-board connector 826 and respective top ends of the second set of interconnection structures 822, i.e., where it is not desired to be covered with a conductive layer to be formed.

Next, as shown in FIG. 8E, a deposition process may be performed to the package substrate 802 at both the front side and the back side to form a first conductive layer 811 on both the first encapsulant layer 810 at the front side and the second encapsulant layer 813 at the back side of the package substrate 802. The first conductive layer 811 can be connected with the first set of interconnection structures 816 and thus electrically coupled thereto.

Next, as shown in FIG. 8F, the conductive layer may be patterned to form one or more antenna patterns 814 at the back side of the package substrate 802, and a shielding layer 812 at the front side of the package substrate 802. The antenna patterns 814 may be electrically coupled to the first set of interconnection structures 816 and thus to the package substrate 802. In some embodiments, a laser ablation process or other similar etching process may be used to pattern the conductive layer. Also, the mask caps can be removed from the package substrate 802 for patterning the conductive layer, thereby exposing both the board-to-board connector 826 and the top ends of the second set of interconnection structures 822.

Next, as shown in FIG. 8G, a third encapsulant layer 818 is formed on the patterned conductive layer at the back side of the package substrate 802, i.e., on the antenna patterns 814. In particular, the second set of interconnection structures 822 may be substantially encapsulated by the third encapsulant layer 818, with their respective top surfaces exposed from the third encapsulant layer 818.

Next, as shown in FIG. 8H, a second conductive layer 821 may be formed on the third encapsulant layer 818, i.e., at the back side of the package substrate 802. In some embodiments where the mask cap enclosing the board-to-board connector 826 may not be removed before the formation of the second conductive layer 821, the second conductive layer 821 may be formed at both sides of the package substrate 802. In that case, the second conductive layer 821 may be deposited on the shielding layer 812 and thus thicken the shielding layer 812. Furthermore, the second conductive layer 821 may be connected with the exposed top surfaces of the second set of interconnection structures 822 and thus electrically coupled thereto. In some embodiments, the second conductive layer 821 may be formed using a deposition process such as a sputtering process.

Next, as shown in FIG. 8I, the second conductive layer may be patterned, for example, using a laser ablation process, to form one or more antenna patterns 822 on the third encapsulant layer 818. The antenna patterns 822 and the antenna patterns 814 are respectively formed on the two encapsulant layers 818 and 813 at different heights from the package substrate 802. It can be appreciated in some other embodiments, more layers of antenna patterns may be formed on the package substrate 802 similarly, which will not be elaborated herein. In this way, the semiconductor package with one or more antenna patterns integrated therein is formed.

The discussion herein includes numerous illustrative figures that show various portions of a semiconductor package and a method for forming the semiconductor package. For illustrative clarity, such figures do not show all aspects of each exemplary method. Any of the example methods provided herein may share any or all characteristics with any or all other methods provided herein.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A semiconductor package, comprising:
a package substrate;
a semiconductor die mounted on the package substrate and electrically coupled to the package substrate;
an encapsulant layer formed on the package substrate to at least encapsulate the semiconductor die;
a shielding layer formed on the encapsulant layer to reduce or prevent electromagnetic interference to the semiconductor die from an external environment of the semiconductor package;
an antenna pattern formed on the encapsulant layer; and
a set of interconnection structures extending through the encapsulant layer and electrically coupled between the antenna pattern and the package substrate.

2. The semiconductor package of claim 1, wherein the antenna pattern and the shielding layer are formed on the encapsulant layer in a single deposition process.

3. The semiconductor package of claim 2, wherein the antenna pattern is patterned using a laser ablation process.

4. The semiconductor package of claim 1, wherein the package substrate comprises a first side and a second side opposite to the first side, the encapsulant layer, the antenna pattern and the shielding layer are all formed on the first side of the package substrate, and the semiconductor package further comprises solder bumps formed on the second side of the package substrate.

5. The semiconductor package of claim 4, further comprising:
an additional encapsulant layer formed on the encapsulant layer, the shielding layer and the antenna pattern;
an additional antenna pattern formed on the additional encapsulant layer; and
a set of additional interconnection structures extending through the encapsulant layer and the additional encapsulant layer and electrically coupled between the additional antenna pattern and the package substrate.

6. The semiconductor package of claim 1, wherein the package substrate comprises a first side and a second side opposite to the first side, the encapsulant layer is formed on both the first and second sides of the package substrate, the semiconductor die is mounted on the first side of the package substrate, the shielding layer is formed on the first side of the package substrate, the antenna pattern is formed on the second side of the package substrate, and wherein the package substrate comprises a connection region exposed from the encapsulant layer where a board to board connector is mounted.

7. The semiconductor package of claim 6, further comprising:
an additional encapsulant layer formed on the encapsulant layer and the antenna pattern at the second side of the package substrate;
an additional antenna pattern formed on the additional encapsulant layer; and
a set of additional interconnection structures extending through the encapsulant layer and the additional encapsulant layer and electrically coupled between the additional antenna pattern and the package substrate.

8. A method for forming a semiconductor package, wherein the method comprises:
providing a package substrate;
mounting on the package substrate a semiconductor die and a set of interconnection structures;
forming on the package substrate an encapsulant layer to encapsulate at least the semiconductor die and the set of interconnection structures, wherein the set of interconnection structures have top surfaces exposed from the encapsulant layer;
forming a conductive layer on the encapsulant layer above both the semiconductor die and the set of interconnection structures, wherein the set of interconnection structures are electrically coupled to the conductive layer; and
patterning the conductive layer to form an antenna pattern and a shielding layer on the encapsulant layer, wherein the antenna pattern is above the set of interconnection structures and electrically coupled to the set of interconnection structures, and the shielding layer is above the semiconductor die.

9. The method of claim 8, wherein patterning the conductive layer comprises patterning the conductive layer using a laser ablation process.

10. The method of claim 8, wherein the package substrate comprises a first side and a second side opposite to the first side, and wherein mounting on the package substrate a semiconductor die and a set of interconnection structures comprises:
mounting the semiconductor die and the interconnection structure on the first side of the package substrate.

11. The method of claim 10, further comprising:
forming solder bumps on the second side of the package substrate.

12. The method of claim 8, wherein the package substrate comprises a first side and a second side opposite to the first side, and wherein mounting on the package substrate a semiconductor die and a set of interconnection structures comprises:
mounting the semiconductor die on the first side of the package substrate; and
mounting the set of interconnection structures on the second side of the package substrate.

13. The method of claim 12, further comprising:
forming on the package substrate a connection region that is exposed from the encapsulant layer; and
mounting on the connection region a board-to-board connector.

14. A method for forming a semiconductor package, wherein the method comprises:
providing a package substrate;
mounting on the package substrate a semiconductor die, a first set of interconnection structures and a second set of interconnection structures, wherein the second set of interconnection structures have a height greater than that of the first set of interconnection structures;
forming on the package substrate an encapsulant layer to encapsulate at least the semiconductor die and the first and second sets of interconnection structures, wherein the first set of interconnection structures have top surfaces exposed from the encapsulant layer, and the second set of interconnection structures have top ends protruding from the encapsulant layer;
forming mask caps on the encapsulant layer to enclose the respective top ends of the second set of interconnection structures;
forming a conductive layer on the encapsulant layer above the semiconductor die and the first and second sets of interconnection structures, wherein the first set of interconnection structures are electrically coupled to the conductive layer;
removing the mask caps from the encapsulant layer to pattern the conductive layer to form an antenna pattern and a shielding layer, wherein the antenna pattern is above the first set of interconnection structures and electrically coupled to the first set of interconnection structures, and the shielding layer is above the semiconductor die;
forming an additional encapsulant layer on the patterned conductive layer;
forming an additional conductive layer on the additional encapsulant layer; and
patterning the additional conductive layer to form an additional antenna pattern on the additional encapsulant layer, wherein the additional antenna pattern is above the second set of interconnection structures and electrically coupled to the second set of interconnection structures.

15. The method of claim 14, wherein patterning the additional conductive layer comprises patterning the additional conductive layer using a laser ablation process.

16. The method of claim 14, wherein the package substrate comprises a first side and a second side opposite to the first side, and wherein mounting on the package substrate a semiconductor die, a first set of interconnection structures and a second set of interconnection structures comprises:
mounting the semiconductor die and the interconnection structure on the first side of the package substrate.

17. The method of claim 16, further comprising:
forming solder bumps on the second side of the package substrate.

18. The method of claim 14, wherein the package substrate comprises a first side and a second side opposite to the first side, and wherein mounting on the package substrate a semiconductor die, a first set of interconnection structures and a second set of interconnection structures comprises:
mounting the semiconductor die on the first side of the package substrate; and
mounting the interconnection structures on the second side of the package substrate.

19. The method of claim 18, further comprising:
forming on the package substrate a connection region that is exposed from the encapsulant layer; and
mounting on the connection region a board to board connector.

20. The method of claim 14, wherein forming on the package substrate an encapsulant layer further comprises:
forming the encapsulant layer using a film assisted molding process.
